(19) United States
(12) Patent Application Publication
(10) Pub. No.: US 2015/0123252 A1
(43) Pub. Date: May 7, 2015

(54) LEAD FRAME PACKAGE AND MANUFACTURING METHOD THEREOF

(71) Applicant: CHIPMOS TECHNOLOGIES INC., Hsinchu (TW)

(72) Inventor: TSUNG JEN LIAO, HSINCHU (TW)

(73) Assignee: CHIPMOS TECHNOLOGIES INC., Hsinchu (TW)

(21) Appl. No.: 14/248,355

(22) Filed: Apr. 9, 2014

(30) Foreign Application Priority Data
Nov. 1, 2013 (TW) 102139711

(51) Int. Cl. H01L 25/10; H01L 21/56; H01L 23/00; H01L 25/00; H01L 23/31

(52) U.S. Cl. CPC H01L 25/105; H01L 25/50; H01L 23/3114; H01L 24/17; H01L 24/81; H01L 21/56; H01L 2225/1058; H01L 2225/1029; H01L 2224/16245; H01L 2224/16113; H01L 2224/811; H01L 2224/81801
USPC 257/673; 438/123

(57) ABSTRACT

The present disclosure relates to a package structure of a lead frame. The package includes a die, a dielectric layer, at least one conducting pillar, at least one lead frame and at least one solder ball. The dielectric layer is disposed on a surface of the die. The at least one conducting pillar penetrates through the dielectric layer and is disposed on the surface. The at least one lead frame is disposed on the dielectric layer and is spaced from the at least one conducting pillar with a gap. The solder ball fills the gap and electrically connects the at least one conducting pillar and the at least one lead frame.

The present application claims priority from Taiwanese application Ser. No. 102139711, filed on Nov. 1, 2013, of the same title and inventorship herewith.

### TECHNICAL FIELD

The present disclosure relates to a package structure and more particularly, to a lead frame package structure.

### BACKGROUND

Current wafer level package technology used for forming a redistribution layer (RDL) and an under bump metallurgy (UBM) is only implemented at a single surface of a substrate, which is either a top surface of the substrate or a bottom surface of the substrate. Thus, it is difficult to form a three-dimensional integrated circuit structure. In addition, the RDL and the UBM at a single surface cannot be used to form a binding of either a wafer to a wafer or a wafer to a die.

### SUMMARY

The present disclosure provides a package structure of a lead frame, which includes a die, a dielectric layer, at least one conducting pillar, at least one lead frame and at least one solder ball.

The die further includes a surface. The dielectric layer is disposed on the surface. The at least one conducting pillar is disposed on the surface and configured to penetrate through the dielectric layer. The at least one lead frame is disposed on the dielectric layer and spaced from the at least one conducting pillar with a gap. The at least one solder ball fills the gap and electrically connects the at least one conducting pillar and the at least one lead frame.

The present disclosure is also related to an integrated circuit with multiple layers. The integrated circuit includes a first package structure and a second package structure. The first package structure and the second package structure include dies, dielectric layers, at least one conducting pillar, at least one lead frame, and at least one solder ball, respectively. The at least one lead frame of the first package structure is electrically connected with the at least one lead frame of the second package structure so as to complete a three-dimensional integrated circuit.

The present disclosure also provides a manufacturing method of a package structure. The manufacturing method includes the following step:

Receiving a die, which includes a surface;

Forming at least one conducting pillar on the surface;

Forming a dielectric layer on the surface, wherein the at least one conducting pillar is configured to penetrate through the dielectric layer;

Disposing or locating at least one lead frame on the dielectric layer, wherein the at least one lead frame is spaced from the conducting pillar with a gap; and

Disposing or locating a solder ball, which fills the gap.

Another function of the present disclosure will be described in the following paragraphs. Certain functions can be realized in the present section, while the other functions can be realized in the detailed description. In addition, the indicated components and the assembly can be explained and achieved by the details of the present disclosure. Notably, the previous explanation and the following description are demonstrated and are not limited to the scope of the present disclosure.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

The foregoing summary, as well as the following detailed description of the invention, will be better understood when read in conjunction with the appended drawings. For the purpose of illustrating the invention, there are examples shown in the drawings which are presently preferred. It should be understood, however, that the invention is not limited to the precise arrangements and instrumentalities shown.

FIG. 1 is a schematic view of a die and at least one conducting pillar disposed thereon in accordance with an embodiment of the present disclosure;

FIG. 2 is a schematic view of a dielectric layer disposed on a surface of the die in accordance with the embodiment of the present disclosure;

FIG. 3 is a schematic view of a lead frame disposed on the dielectric layer in accordance with an embodiment of the present disclosure;

FIG. 4 is a top view of a lead frame spaced from at least one conducting pillar with a gap in accordance with an embodiment of the present disclosure;

FIG. 5 is a cross-sectional view of the at least one lead frame encircling the at least one conducting pillar with a gap in accordance with an embodiment of the present disclosure;

FIG. 6 is a top view of at least one solder ball filling the gap in accordance with an embodiment of the present disclosure;

FIG. 7 is a schematic view of a package structure with a plurality of lead frames in accordance with an embodiment of the present disclosure;

FIG. 8 is a schematic view of a package structure with a plurality of lead frames, which is covered by an encapsulation layer in accordance with an embodiment of the present disclosure;

FIG. 9 is a schematic view of a base layer in accordance with an embodiment of the present disclosure;

FIG. 10 is a schematic view of a base layer and a metal layer in accordance with an embodiment of the present disclosure;

FIG. 11 is a schematic view of locating a photoresist on the metal layer for lithography in accordance with an embodiment of the present disclosure;

FIG. 12 is a schematic view of a hole formation resulting from etching the metal layer in accordance with an embodiment of the present disclosure;

FIG. 13 is a schematic view of removing a photoresist pattern in accordance with an embodiment of the present disclosure;

FIG. 14 is a schematic view of flipping a die over the etched metal layer in accordance with an embodiment of the present disclosure;

FIG. 15 is a schematic view of locating a lead frame under the metal layer in accordance with an embodiment of the present disclosure;

FIG. 16 is a schematic view of an encapsulation layer located on the die in accordance with an embodiment of the present disclosure;

FIG. 17 is a top view of locating the lead frame, which encircles each of the conducting pillars in accordance with an embodiment of the present disclosure;

FIG. 18 is a schematic view of removing a portion of the metal layer and removing a portion of the encapsulation layer for planting a solder ball in accordance with an embodiment of the present disclosure;

FIG. 19 is a top view of the solder ball filling a plurality of gaps and covering the conducting pillar in accordance with an embodiment of the present disclosure; and

FIG. 20 is a schematic view of stacking a plurality of package structures as shown in FIG. 18 in accordance with an embodiment of the present disclosure.

### DETAILED DESCRIPTION

In the present disclosure, the manufacturing method of a lead frame package structure includes, but is not limited to, the following steps according to various embodiments and may be modified or have certain features deleted in accordance with different design purposes.

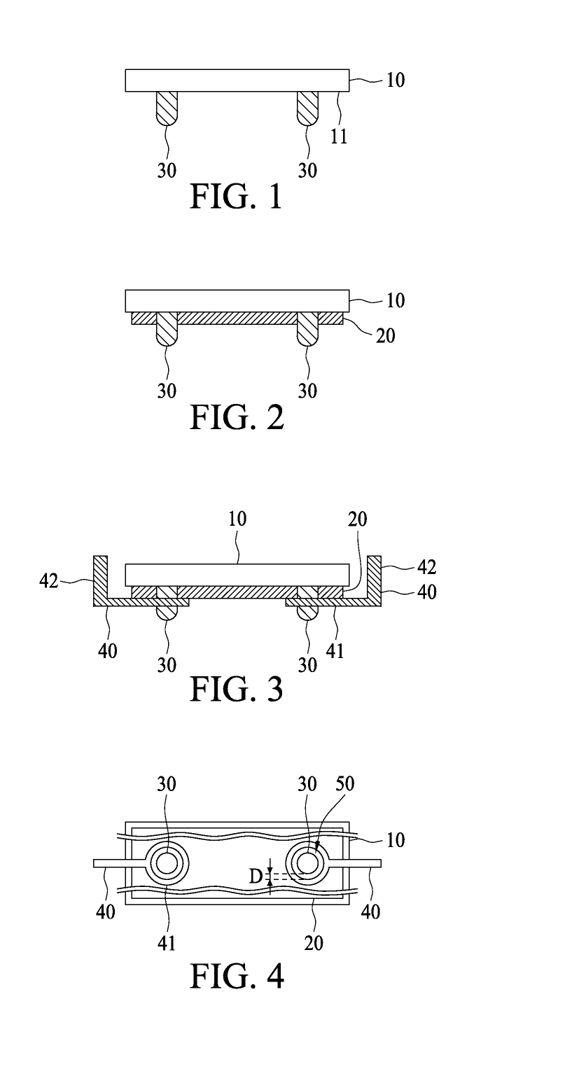

Referring to FIG. 1, a die 10 is provided. The die 10 includes a surface 11.

In some embodiments, at least one conducting pillar 30 is formed on the surface 11. In the specification and patent scope, the term “on” means that a first member is directly or indirectly disposed above the second member. For instance, “at least one conducting pillar 30 is disposed on the surface 11” means two embodiments. The first embodiment means that the at least one conducting pillar 30 is directly disposed on the surface 11. The second embodiment means that the at least one conducting pillar 30 is indirectly disposed above the surface 11. The term “indirectly” means that in a vertical view, two members are disposed at an upper position and a lower position, respectively, while other objects, material layers, or gaps are disposed between the two members. In addition, the conducting pillar 30 may be an electroplated copper pillar or other metal materials with conductive properties.

As shown in FIG. 2, a dielectric layer 20 is formed on the surface 11, but the dielectric layer 20 does not cover the conducting pillar 30. In other words, the conducting pillar 30 penetrates through the dielectric layer 20. As shown in FIG. 2, the conducting pillar 30 protrudes from the dielectric layer 20 atop the surface 11 of the die 10.

As shown in FIG. 3, at least one lead frame 40 is disposed or located on the dielectric layer 20. In some embodiments, the lead frame 40 includes a connection portion 41 and a support portion 42. The connection portion 41 and the support portion 42 form, but are not limited to, an L shape. In other words, the connection portion 41 is connected with the support portion 42 and is perpendicular to the support portion 42. In certain embodiments (not shown), the connection portion 41 and the support portion 42 are designed to form other structures.

As shown in FIG. 4, the connection portion 41 of the lead frame 40 has a terminal, which is in a circular shape or rectangular frame shape. The connection portion 41 of the lead frame 40 is spaced from the conducting pillar 30 with a gap 50. The gap 50 has a predetermined distance D, which is adjustable in order to connect or accommodate a solder ball. In certain embodiments (not shown), the terminal of the connection portion 41 may be in a linear shape or strip shape. In such embodiments, the terminal of the connection portion 41 is spaced from the conducting pillar 30 with a gap 50.

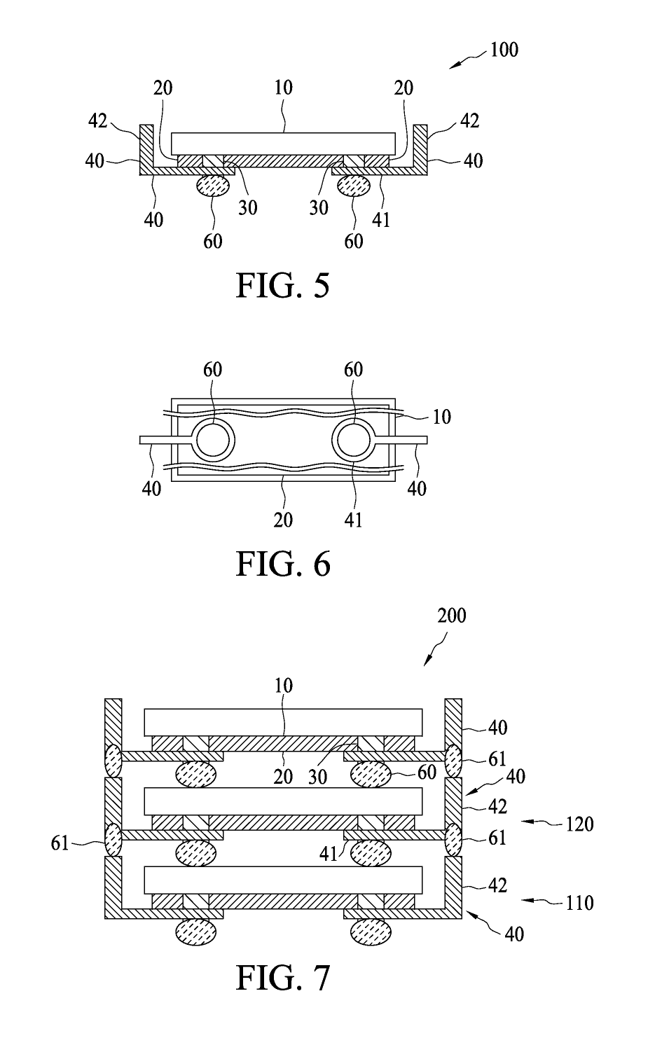

As shown in FIG. 5, at least one solder ball 60 is disposed so as to fill the gap 50. Particularly, the solder ball 60 is disposed on the conducting pillar 30 in order to connect with a terminal of the connection portion 41 of the lead frame 40. Thus, the solder ball 60 acts as a connecting terminal with an external device. As shown in FIG. 6, the solder ball 60 electrically connects the conducting pillar 30 and the lead frame 40 so as to transmit electric signals through the lead frame 40. In other words, the present disclosure electrically connects at least one solder ball 60, at least one conducting pillar 30, and at least one lead frame 40.

In the embodiments, prior to a location of the solder ball 60, the connection portion 41 encircles the at least one conducting pillar 30. After the solder ball 60 fills the gap, the solder ball 60 electrically connects the connection portion 41 of the lead frame 40 and fixes the lead frame 40 and the conducting pillar 30. The formation of the solder ball 60 is implemented by several steps. Initially, solder paste is formed on the connection portion 41 and the conducting pillar 30 and then subsequently reflowed so as to form the solder ball. In other embodiments, the solder material is disposed on the connection portion 41 and the conducting pillar 30. Afterward, the solder ball 60 is formed on the conducting pillar 30 by a ball drop method or electroplating method.

As shown in FIGS. 5 and 6, the package structure 100 of the lead frame in the present disclosure includes a die 10, a dielectric layer 20, at least one conducting pillar 30, at least one lead frame 40 and at least one solder ball 60. Although the embodiments illustrate two conducting pillars 30, two lead frames 40 and two solder balls 60, the package structure 100 of the present disclosure is implemented by a single conducting pillar 30, a single lead frame 40 and a single solder ball 60. In some embodiments, the package structure 100 of the present disclosure is implemented by more than two units of the conducting pillars 30, lead frames 40 and solder balls. Therefore, the embodiments of the present disclosure are not necessary limited to the drawings.

As shown in FIG. 7, the integrated circuit 200 with multiple layers in the present disclosure includes a plurality package structures with the lead frame. In the embodiment, the support portion 42 of at least one lead frame 40 in the first package structure 110 electrically connects with another lead frame 40 of the second package structure 120. Particularly, a connection solder ball 61 electrically connects the support portion 42 of the first package structure 110 and the support portion 42 of the second package structure 120. In addition, the solder ball 60 of each package structure may be disposed on a surface of adjacent die so as to increase the stability of the stacking of those package structures. In certain embodiments, although the integrated circuit 200 with multiple layers includes three lead frame package structures, the integrated circuit 200 is also implemented by two, or more than two, lead frame package structures.

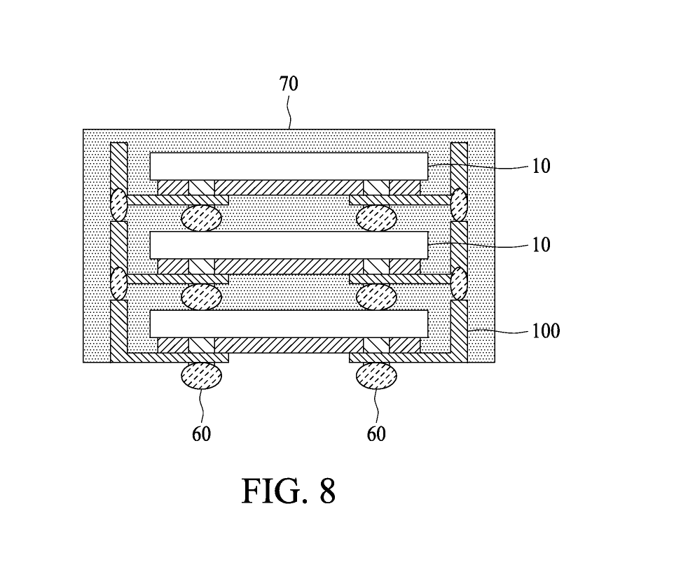

As shown in FIG. 8, an encapsulation layer 70 covers a plurality of dies 10. Particularly, the encapsulation layer 70 covers a major portion of the integrated circuit 200 with multiple layers and exposes the solder ball 60 of the bottom lead frame package structure 100.

The present disclosure also provides another manufacturing method of a lead frame including, but not limited to, the following steps according to various embodiments and may be modified or have certain features deleted in accordance with different design purposes.

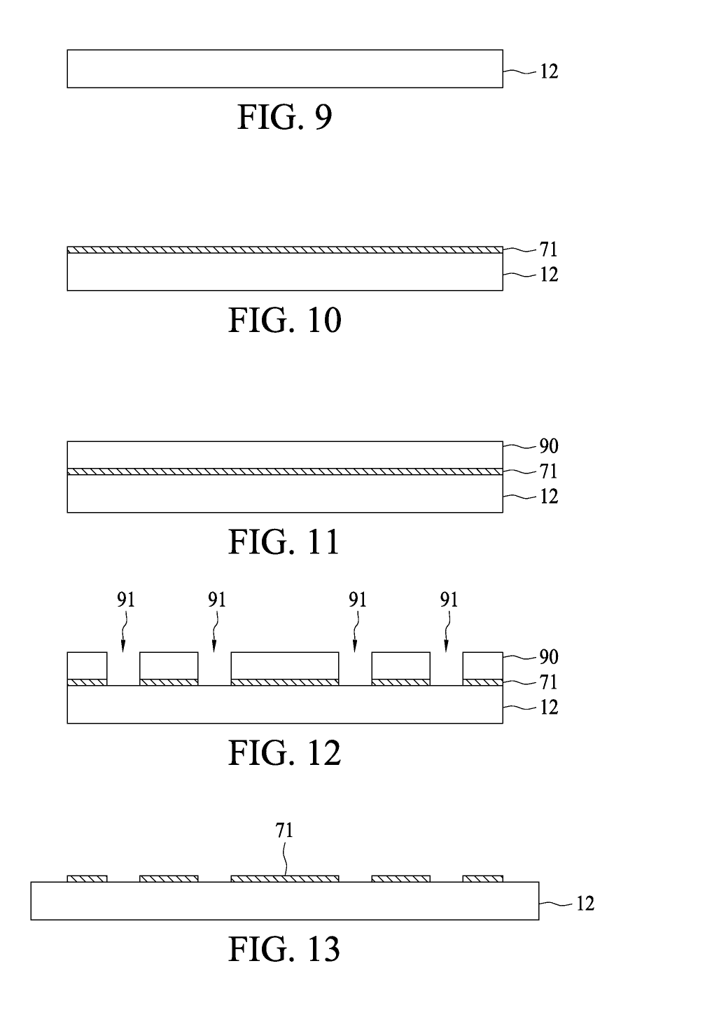

As shown in FIGS. 9 and 10, a metal layer 71 (such as a copper film) is disposed on a substrate 12. The substrate 12 may be metal, glass, or a silicon substrate used for fabricating devices thereon.

As shown in FIGS. 11 and 12, a photoresist 90 is disposed on the metal layer 71 and then forms a pattern on the photoresist 90. Particularly, the patterned photoresist 90 exposes a certain area 91. The metal layer 71 under the exposed area 91 will be further etched.

As shown in FIG. 13, the patterned photoresist 90 is removed. Subsequently, the etched metal layer 71 is maintained on the substrate 12.

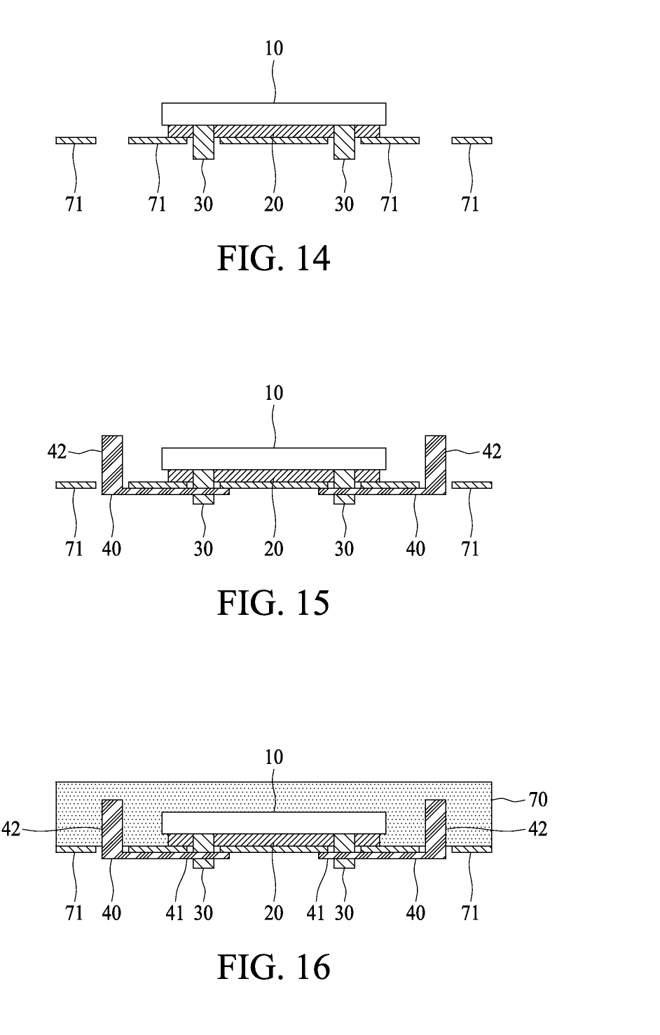

As shown in FIG. 14, after the substrate 12 is removed, the die 10 is flipped and facing downward so as to allow the conducting pillar 30 to penetrate through the aperture of the etched metal layer 71. Thus, the dielectric layer 20 is allowed to be disposed on the metal layer 71.

As shown in FIG. 15, the lead frame 40 is disposed under the metal layer 71. When the connection portion 41 allows the conducting pillar 30 to penetrate through the hole of the connection portion 41, the support portion 42 of the lead frame 40 passes through the apertures of the etched metal layer 71.

As shown in FIG. 16, an encapsulation process is implemented to allow the encapsulation layer 70 to cover the die 10, the metal layer 71, and the lead frame 40. The support portion 42 protrudes inside the encapsulation layer 70. Thus, the support portion 42 may improve the strength of the encapsulation layer 70.

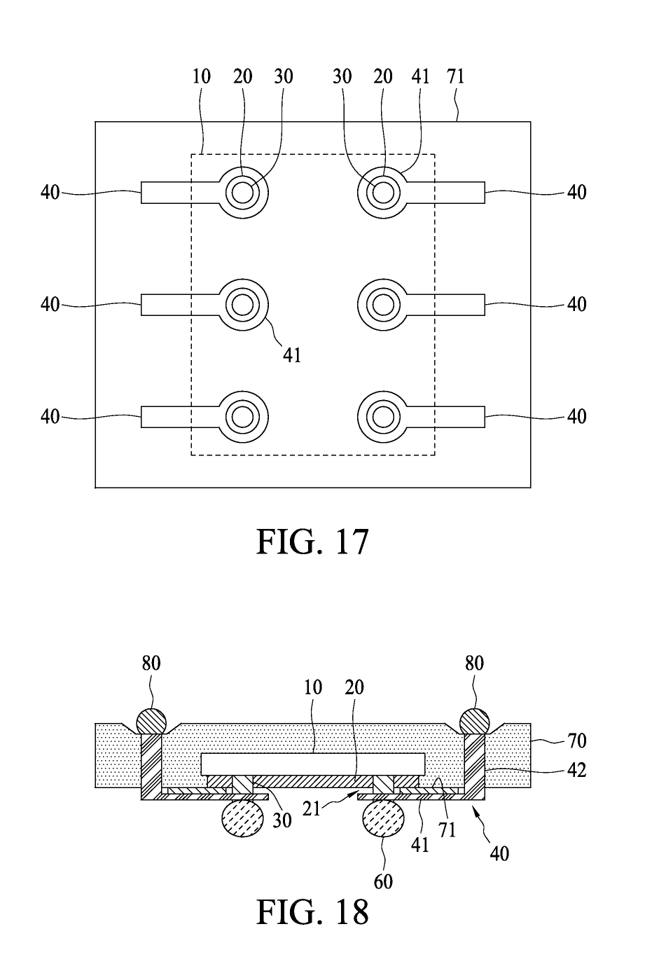

As shown in FIG. 17, the connection portion 41 of the lead frame 40 encircles the conducting pillar 30. Since the metal layer 71 does not directly contact the conducting pillar 30, the dielectric layer 20 between the connection portion 41 and the conducting pillar 30 is exposed.

As shown in FIG. 18, a portion of the metal layer 71 on the dielectric layer 20 and between two conducting pillars 30 is removed so as to form an opening 21 between the lead frame 40 and the dielectric layer 20. Particularly, the opening 21 between the connection portion 41 of the lead frame 40 and the dielectric layer 20 is utilized for heat dissipation of the lead frame 40 or dielectric layer 20 so as to avoid overheating of the die. In addition, a portion of the metal layer 71 is disposed between the connection portion 41 and the encapsulation layer 70 so as to conduct the heat from the dielectric layer 20 to a lateral side of the encapsulation layer 70. Thus, the heat dissipation of the three-dimensional integrated circuit is achieved.

As shown in FIG. 18, after the support portion 42 of the lead frame 40 penetrates through the encapsulation layer 70, a portion of the encapsulation layer 70 is removed so as to expose a portion of the support portion 42. The encapsulation layer removal step is implemented by an etching process such as a CO₂ laser etching process. After the support portion 42 is exposed, a solder ball 80 is electrically connected to a backside of the encapsulation layer 70. In another embodiment, the encapsulation layer removal step is performed by grinding a backside of the encapsulation layer 70 so as to expose the support portion 42. Subsequently, a solder ball 80 is electrically connected to the support portion 42. Particularly, the solder ball 80 is disposed on the support portion 42. Moreover, in this case, the solder ball 60 is also disposed on the conducting pillar 30. Since the support portion 42 of the lead frame 40 acts as a backbone of the encapsulation layer 70 so as to enhance the strength of the encapsulation layer 70, the encapsulation layer 70 can maintain its original shape and does not form a warpage, which is caused due to the stacking of the encapsulation layer 70. Furthermore, current wafer level package technology used for forming a redistribution layer (RDL) and an under bump metallurgy (UBM) is only implemented at a single surface of a substrate, which is either a top surface of the substrate or a bottom surface of the substrate. Since the backside solder ball 80 is disposed on the support portion 42, the present disclosure is able to achieve a two-surface distribution of the electric circuit. In other words, it is possible to form a three-dimensional integrated circuit structure.

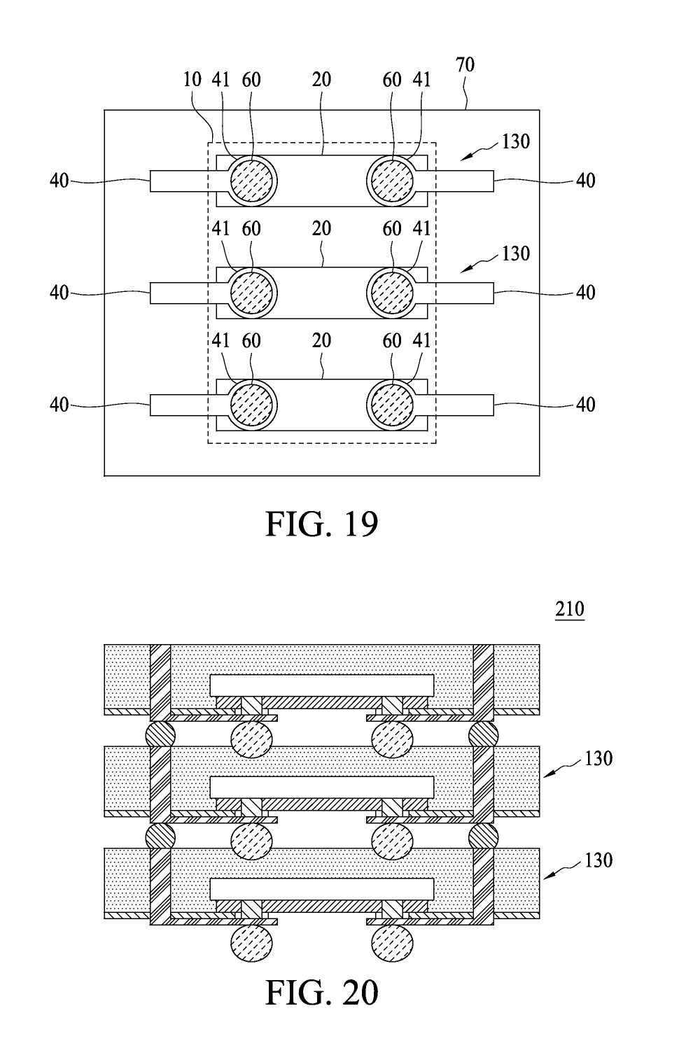

As shown in FIG. 19, the solder ball 60 connects the connection portion 41 of the lead frame 40 and the conducting pillar. In other words, the die 10 is electrically connected to the backside solder ball 80 through the conducting pillar 30, the solder ball 60, the connection portion 41, and the support portion 42 so as to transmit electric signals to a backside of the encapsulation layer 70. In the embodiments, a terminal of the connection portion 41 of the lead frame 40 may be in a circular shape or a frame shape. In another embodiment (not shown), the terminal of the connection portion 41 can be in a linear shape or a strip shape. In the embodiment shown in FIG. 17, a plane may include a plurality of the package structures 130.

As shown in FIG. 20, the above-mentioned package structures 130 may be stacked up in a vertical direction so as to form another integrated circuit 210 with multiple layers.

Although the present disclosure and its advantages have been described in detail, it should be understood that various changes, substitutions, and alterations can be made herein without departing from the spirit and scope of the disclosure as defined by the appended claims. For example, many of the processes discussed above can be implemented in different methodologies and replaced by other processes, or a combination thereof.

What is claimed is:

1. A package structure of a lead frame, comprising:
a die including a surface;
a dielectric layer disposed on the surface;
at least one conducting pillar disposed on the surface and configured to penetrate through the dielectric layer;
at least one lead frame disposed on the dielectric layer and spaced from the at least one conducting pillar with a gap; and
at least one connection solder ball for filling the gap and electrically connecting the at least one conducting pillar and the at least one lead frame.

2. The package structure according to claim 1, wherein the at least one lead frame includes a connection portion electrically connecting with the at least one connection solder ball, the connection portion surrounds the at least one conducting pillar, and a gap is between the connection portion and the at least one conducting pillar.

3. The package structure according to claim 2, wherein the at least one lead frame further includes a support portion connecting with the connection portion and the support portion is perpendicular to the connection portion.

4. The package structure according to claim 2, further comprising an encapsulation layer covering the die.

5. The package structure according to claim 4, wherein the at least one lead frame includes a support portion, and the support portion is configured to penetrate through the encapsulation layer and electrically connect to at least one solder ball.

6. The package structure according to claim 5, further comprising a metal layer, wherein the at least one lead frame further includes the connection portion, the metal layer is disposed between the connection portion and the encapsulation layer, the connection portion is electrically connected with the at least one connection solder ball, and the connection portion surrounds the at least one conducting pillar.

7. The package structure according to claim 6, wherein the connection portion is spaced from the dielectric layer with a distance.

8. An integrated circuit with multiple layers, comprising:
a first package structure according to claim 1; and
a second package structure according to claim 1;
wherein the at least one lead frame of the first package structure is electrically connected with the at least one lead frame of the second package structure.

9. The integrated circuit according to claim 8, wherein the at least one lead frame includes a connection portion electrically connecting with the at least one connection solder ball, the connection portion surrounds the at least one conducting pillar, and a gap is between the connection portion and the at least one conducting pillar.

10. The integrated circuit according to claim 8, further comprising an encapsulation layer covering the die.

11. The integrated circuit according to claim 10, wherein the at least one lead frame of the first package structure includes a support portion, and the support portion is configured to penetrate through the encapsulation layer and electrically connect to at least one solder ball.

12. A manufacturing method of a package structure, comprising:
receiving a die, including a surface;
forming at least one conducting pillar on the surface;
forming a dielectric layer on the surface, wherein the at least one conducting pillar is configured to penetrate through the dielectric layer;
disposing at least one lead frame on the dielectric layer, wherein the at least one lead frame is spaced from the at least one conducting pillar with a gap; and
disposing a solder ball, wherein the solder ball fills the gap.

13. The manufacturing method according to claim 12, further comprising a step of electrically connecting the at least one solder ball, the at least one conducting pillar, and the at least one lead frame.

14. The manufacturing method according to claim 12, wherein the at least one lead frame includes a connection portion and the manufacturing method further comprises a step of electrically connecting the connection portion and the at least one solder ball, and encircling the at least one conducting pillar through the connection portion.

15. The manufacturing method according to claim 13, wherein the at least one lead frame further includes a support portion, the support portion connects with the connection portion, and the support portion is perpendicular to the connection portion.

16. The manufacturing method according to claim 15, further comprising a step of covering the die through an encapsulation layer.

17. The manufacturing method according to claim 16, further comprising a step of disposing a metal layer on the dielectric layer.

18. The manufacturing method according to claim 17, further comprising a step of removing a portion of the encapsulation layer so as to expose the support portion.

19. The manufacturing method according to claim 18, further comprising a step of disposing at least one solder ball on the exposed support portion.

20. The manufacturing method according to claim 18, wherein the encapsulation layer removal step further includes a step of etching or grinding the encapsulation layer.
